(19) United States
(12) Patent Application Publication
(10) Pub. No.: US 2017/0323857 A1
(43) Pub. Date: Nov. 9, 2017

(54) ELECTRONIC CIRCUIT COMPONENT

(71) Applicant: DENSO CORPORATION, Kariya-city, Aichi-pref. (JP)

(72) Inventor: Masatada Yoshida, Kariya-city, Aichi-pref. (JP)

(21) Appl. No.: 15/522,519

(22) PCT Filed: Oct. 29, 2015
(86) PCT No.: PCT/JP2015/005449

§ 371 Date: Apr. 27, 2017

(30) Foreign Application Priority Data
Oct. 31, 2014 (JP) 2014-222839

(51) Int. Cl. H01L 23/00; H01L 23/495; H01L 21/56; H01L 21/48; H01L 23/13; H01L 23/057; H01L 25/16; H01L 23/498; H01L 23/50

(52) U.S. Cl. CPC H01L 23/562; H01L 25/16; H01L 23/49551; H01L 21/565; H01L 23/49861; H01L 21/4803; H01L 23/13; H01L 23/057; H01L 23/49589; H01L 23/50

(57) ABSTRACT

An electronic circuit component includes: an electronic component; a leadframe that forms a circuit pattern corresponding to an arrangement of the electronic component; a resin element in which a part of the leadframe is disposed by insert molding; a first lid element that covers a first surface of the resin element on which the electronic component is arranged, the first surface of the resin element including a concave land in which the electronic component is arranged; and terminal portions that are arranged on a bottom surface of the land. The terminal portions are a part of the leadframe and are electrically connected to the electronic component. A part of the first lid element that is opposed to the land includes a recess that defines a clearance between the electronic component and the first lid element.

### CROSS REFERENCE TO RELATED APPLICATION

This application is based on Japanese Patent Application No. 2014-222839 filed on Oct. 31, 2014, the disclosure of which is incorporated herein by reference.

### TECHNICAL FIELD

The present disclosure relates to an electronic circuit component.

### BACKGROUND ART

An electronic circuit is mainly made up of electronic components (electronic elements) such as a capacitor, a diode, an IC, and an electronic circuit component having a circuit pattern on which the electronic components are mounted. The electronic circuit component may also be a substrate component having a circuit pattern formed of a conductor (for example, a plating or lead material). Examples of the electronic circuit component include a printed circuit board, a resin with pattern plating, and a copper lead component.

The resin with pattern plating is described in JP2003-204179A. For example, JP2003-28890A describes mounting of an electronic component on a copper lead component (connector terminal). The printed circuit board or the resin with pattern plating requires wiring formation with a copper foil or by plating, leading to a problem in manufacturing cost. On the other hand, the copper lead component is beforehand provided with a wiring with a lead material to reduce manufacturing cost.

### PRIOR ART DOCUMENTS

### Patent Documents

Patent Document 1: JP2003-204179A.

Patent Document 2: JP2003-28890A.

In such an existing copper lead component, when the electronic component is fixed on the wiring, solder easily spreads and is thus difficult to have a desired film thickness. In other words, the existing copper lead component has a problem that a designed solder fillet is less likely to be formed. The solder must have the film thickness to withstand thermal shock caused by repetition of high and low temperatures.

The engineering department to which the inventors belong therefore has completed a new electronic circuit component, in which a leadframe is molded by a resin, and a land is formed at a position where an electronic component with such a resin element is disposed. A solder with a desired film thickness can be easily provided. This electronic circuit component as a whole is finally overmolded (secondary-molded) with a resin. A side (land side), on which the electronic component is disposed, of the resin element must be covered with a lid element in order to prevent the overmolding resin from entering the land during molding.

The inventors have found a problem that the lid element is pressed from the outside and thus deformed by the pressure during the overmolding, which may cause stress to the electronic component. Such application of stress to the electronic component may lead to occurrence of a trouble such as disconnection between the leadframe and the electronic component.

### SUMMARY OF INVENTION

The present disclosure addresses the above issues. Thus, it is an objective of the present disclosure to provide an electronic circuit component capable of suppressing stress applied to the electronic component during overmolding.

To achieve the objective, an electronic circuit component in an aspect of the present disclosure includes: an electronic component; a leadframe that forms a circuit pattern corresponding to an arrangement of the electronic component; a resin element in which a part of the leadframe is disposed by insert molding; a first lid element that covers a first surface of the resin element on which the electronic component is arranged, the first surface of the resin element including a concave land in which the electronic component is arranged; and a plurality of terminal portions that is arranged on a bottom surface of the land. The plurality of terminal portions is a part of the leadframe and is electrically connected to the electronic component. A part of the first lid element that is opposed to the land includes a recess that defines a clearance between the electronic component and the first lid element.

According to such a configuration, since a recess corresponding to a land is provided in a first lid element, even if a first lid element is deformed by later overmolding, such deformation is absorbed by a clearance, resulting in suppression of stress applied to the electronic component.

### BRIEF DESCRIPTION OF DRAWINGS

The above and other objects, features and advantages of the present disclosure will become more apparent from the following detailed description made with reference to the accompanying drawings. In the drawings:

FIG. 1 is a structural diagram illustrating a schematic configuration of an electronic circuit component of a first embodiment;

FIG. 2 is a structural diagram illustrating a configuration excluding a first lid element of the electronic circuit component of the first embodiment;

FIG. 3 is an explanatory plan view to explain a first land of the first embodiment;

FIG. 4 is an explanatory plan view to explain a second land of the first embodiment;

FIG. 5 is an explanatory section view to explain the first land of the first embodiment;

FIG. 6 is an explanatory section view to explain the second land of the first embodiment;

FIG. 7 is an explanatory section view to explain the electronic circuit component of the first embodiment;

FIG. 8 is an explanatory back view to explain the first lid element of the first embodiment;

FIG. 9 is an explanatory section view to explain a modification of the electronic circuit component of the first embodiment;

FIG. 10 is an explanatory section view to explain an electronic circuit component of a second embodiment;

FIG. 11 is an explanatory section view to explain a modification of the electronic circuit component of the second embodiment;

FIG. 12 is an explanatory section view to explain an electronic circuit component of a third embodiment;

FIG. 13 is an explanatory plan view to explain an electronic circuit component of a fourth embodiment;

FIG. 14 is an explanatory side view to explain the electronic circuit component of the fourth embodiment; and

FIG. 15 is an explanatory side view to explain an electronic circuit component of the fourth embodiment.

### EMBODIMENTS FOR CARRYING OUT INVENTION

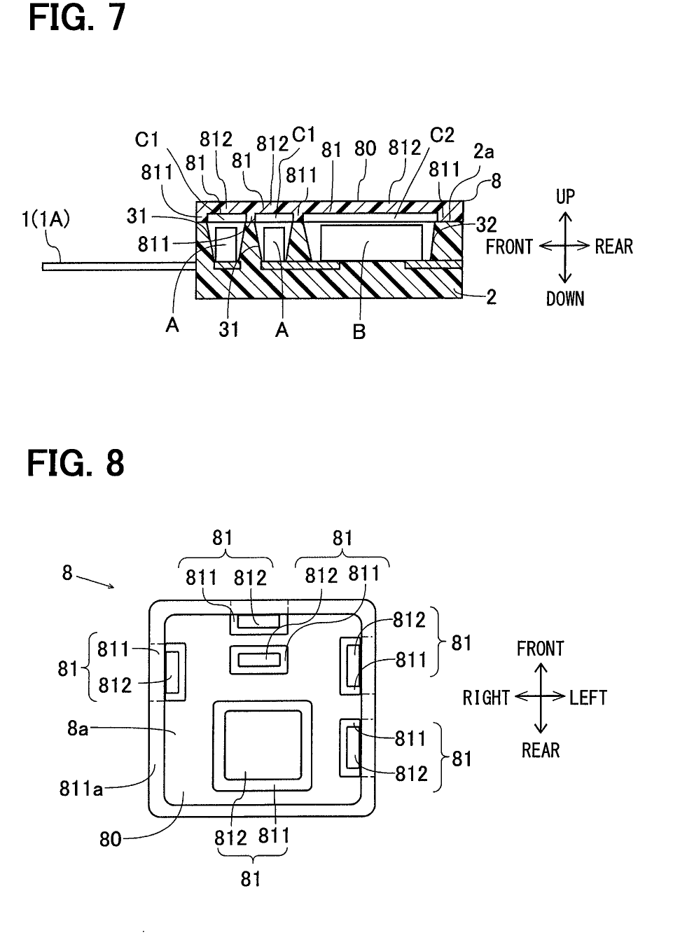

Hereinafter, some embodiments will be described with reference to the accompanying drawings. In the following embodiments, the same or equivalent portions are denoted by the same reference numerals in the drawings. In addition, each drawing used for explanation is a conceptual diagram, and the shape of each part may not be necessarily precise. In FIG. 2, a first lid element 8 is omitted. In FIGS. 7 and 9 to 12, anchor parts 6 and 7 are omitted.

### First Embodiment

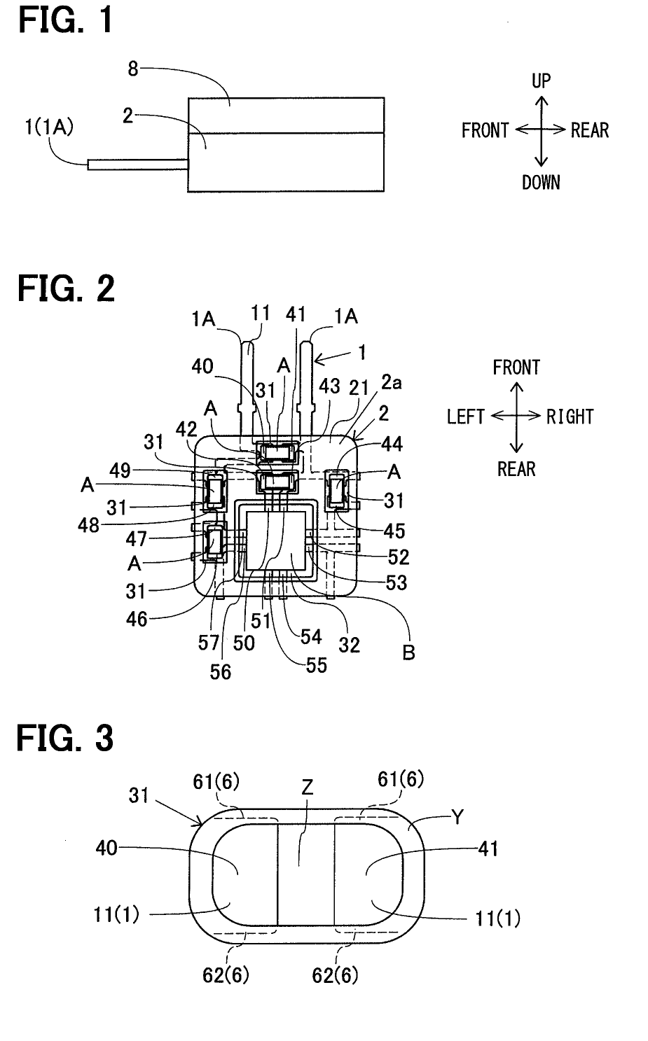

As shown in FIGS. 1 to 8, an electronic circuit component of a first embodiment includes electronic components A and B, a leadframe 1, a resin element 2, and a first lid element 8. The electronic components A and B are each an element configuring an electronic circuit, for example, a capacitor, a resistance, an IC enclosed in a package. In the first embodiment, the electronic component A is a capacitor or a resistive element, and the electronic component B is an IC.

As shown in FIG. 2, the leadframe 1 includes a conductive flat wiring and has a circuit pattern corresponding to the electronic components A and B to be mounted. The leadframe 1 is a circuit forming element formed by punching a conductive alloy sheet, for example. Part of the leadframe 1 is disposed within the resin element 2 by insert molding. The leadframe 1 includes a plurality of lead parts 11. The lead parts 11 configures a wiring connecting each of the electronic components A and B to an external device. As will be described later, the leadframe 1 includes terminal portions 40 to 57.

The resin element 2 formed of resin is a substrate forming element that has a shape of substantially rectangular parallelepiped while having part of the leadframe 1 disposed therein by insert molding. Concave lands 31 and 32 corresponding to the respective sizes of the electronic components A and B are provided at the disposed positions of the electronic components A and B in a first surface 2a (top) of the resin element 2. In other words, the resin element 2 has a plate-like substrate forming portion 21 and a plurality of lands 31 and 32. In FIG. 2, the leadframe 1 within the resin element 2 is represented by a broken line for explanation.

As shown in FIGS. 3, 4, 5, and 6, the lands 31 and 32 each have a side face (inner side face) Y and a bottom (inner bottom) Z. The land 31 is formed into a size capable of accommodating the electronic component A, and the land 32 is formed into a size capable of accommodating the electronic component B. In the description, a side, on which the electronic components A and B are disposed, of the resin element 2 of the first embodiment is referred to as upside, and the opposite side of the upside is referred to as downside. In addition, one planar direction orthogonal to the vertical direction is referred to as longitudinal direction, and a direction orthogonal to both the vertical direction and the longitudinal direction is referred to as horizontal direction. Note that “upside”, “front”, or “left” can be replaced with “one”, and “downside”, and “rear” or “right” can be replaced with “the other”. The top of the resin element 2 is referred to as surface, and the lower surface of the resin element 2 is referred to as back.

As shown in FIGS. 2 to 4, a plurality of terminal portions 40 to 57, each being part of the leadframe 1, are disposed on the bottom (surface) Z of the land 31 or 32. The terminal portions 40 to 57 are each formed in such a manner that part of the leadframe 1 is exposed from the resin element 2 so as to be electrically connectable to the electronic component A or B on the bottom Z of the land 31 or 32. The land 31 or 32 has a rectangular shape (including one having rounded corners) as viewed from the upside.

As shown in FIGS. 5 and 6, the land 31 or 32 is formed such that a clearance between opposing side faces Y increases as going from the bottom Z to the opening side (upside). In the first embodiment, the clearance gradually increases as going to the upside. FIG. 5 is a diagram conceptually showing part of a cross section, which is taken along a plane extending in both the longitudinal and vertical directions, of the land 31 on which the terminal portions 40 and 41 are disposed. FIG. 6 is a diagram conceptually showing part of a cross section, which is taken along a plane extending in both the longitudinal and vertical directions, of the land 32. The explanatory plan view means a conceptual view as viewed from the upside.

The land 31 has a rectangular shape as viewed from the upside in accordance with the electronic component A. The terminal portion 40 as part of one lead part 11 and the terminal portion 41 as part of another lead part 11 are disposed on the bottom Z of the land 31. The terminal portions 40 and 41 are embedded in the bottom Z of the land 31 while being spaced apart from each other such that their surfaces (tops) are exposed. As viewed from the upside, the terminal portion 40 is disposed at the left end of the land 31, and the terminal portion 41 is disposed at the right end of the land 31. The respective terminal portions 40 and 41 are disposed at the positions corresponding to the terminals of the electronic component A.

As shown in FIGS. 3 and 5, width in the longitudinal direction of the lead part 11 including the terminal portion 40 or 41 is partially larger than width of the short side of the land 31 (width in the longitudinal direction). That is, a first anchor part 6 extending in a planar direction within the resin element 2 is provided on each of the side faces (the front side face and the rear side face) in the planar direction of the terminal portion 40 or 41. The first anchor part 6 is embedded in the resin element 2. The first anchor part 6 includes a front anchor part 61 extending forward from the front side face of the terminal portion 40 or 41 and a rear anchor part 62 extending rearward from the rear side face of the terminal portion 40 or 41.

The electronic component A is disposed in the land 31. The terminals of the electronic component A are fixed by solder to corresponding terminal portions 40 to 49. The configurations of the terminal portions 42 and 43 disposed in another land 31 are the same as those of the terminal portions 40 and 41, respectively. The configurations of the terminal portions 44 and 45, 46 and 47, or 48 and 49 disposed in other lands 31 are the same as those of the terminal portions 40 and 41 or 42 and 43, respectively, except that the front and rear as well as the left and right are exchanged with respect to the terminal portions 40 and 41 or 42 and 43. That is, the terminal portions 44 and 45, 46 and 47, or 48 and 49 are disposed in the front and rear end portions of the corresponding land 31. The first anchor parts 6 (a left anchor part 61 and a right anchor part 62) are formed on both side faces (a left side face and a right side face) in the planar direction of each of the terminal portions 44 to 49.

The land 32 has a square shape as viewed from the upside in accordance with the electronic component B. Terminal portions 50 to 57 are disposed on the bottom Z of the land 32. Each of the terminal portions 50 to 57 includes one end portion of the corresponding lead part 11. The terminal portions 50 to 57 are each embedded in the bottom Z of the land 32 in such a manner that the surface of the one end portion of the corresponding lead part 11 is exposed.

The terminal portions 50 to 57 each have a rectangular shape, and are disposed at positions corresponding to the terminals of the electronic component B. The terminal portions 50 to 57 are spaced apart from one another, and are arranged two by two in parallel on one side of the square shape. The electronic component B is disposed in the land 32. The eight terminals of the electronic component B are fixed by solder to the corresponding terminal portions 50 to 57.

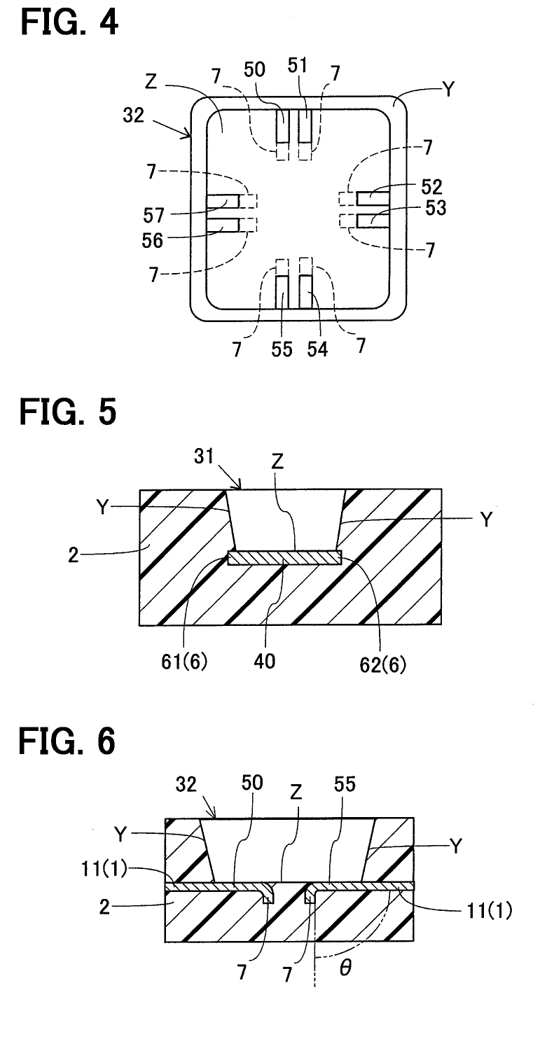

As shown in FIGS. 4 and 6, a second anchor part 7 is provided at an end of each of the terminal portions 50 to 57, the end being close to the middle of the land 32 (one end being not close to a side in the planar direction), while extending to the downside (back side) from the end. The second anchor part 7 is formed by downwardly bending a tip portion of the corresponding lead part 11. The second anchor part 7 is embedded in the resin element 2. In the first embodiment, the second anchor part 7 has a rectangular parallelepiped shape. In the first embodiment, an angle θ defined by the second anchor part 7 and each of the terminal portions 50 to 57 is, but not limited to, about 90°. In other words, although the second anchor part 7 is formed through bending the tip portion in a right angle direction (θ=90° with respect to each of the terminal portions 50 to 57, the bending direction may be a direction other than the right angle direction, i.e., the angle θ may be 0°<θ<90° or 90°<θ<180°.

In this way, the leadframe 1 is configured of the terminal portions 40 to 57, the first anchor part 6, the second anchor part 7, and a wiring portion configuring a circuit wiring (including a connector terminal part 1A). Each of the terminal portions 40 to 57 includes part of the leadframe 1, which is exposed from the resin element 2 so as to be electrically connectable to the electronic component A or B. The connector terminal part 1A is exposed from the resin element 2 and configures a connector terminal disposed inside a connector case 91 described later.

In the first embodiment, the sidewall (side face) Y of the land 31 or 32 has a height such that the electronic component A or B does not project from the first surface 2a (see FIG. 7). That is, the depths of the lands 31 and 32 are larger than the heights of the electronic components A and B, respectively. Consequently, the electronic components A and B are more stably disposed in the lands 31 and 32, respectively.

As shown in FIG. 7, the first lid element 8 is a resin element for covering the first surface 2a of the resin element 2, and is disposed on the first surface 2a. The first lid element 8 is manufactured separately from the resin element 2. As shown in FIGS. 7 and 8, the first lid element 8 has a recess 81 at a portion opposed to each of the lands 31 and 32. In other words, the recess 81 is provided in a portion, which is opposed to the land 31 or 32, of the first lid element 8. Specifically, the recess 81 includes a rib 811 disposed on the entire periphery of the land 31 or 32, and a bottom portion 812 forming the bottom of the recess 81 with the rib 811 as a sidewall. That is, the first lid element 8 includes at least a substantially plate-like main body portion 80 including the bottom portion 812 and the rib 811 projecting downward from the lower surface of the main body portion 80.

The rib 811 is disposed so as to surround the opening of the land 31 or 32. The rib 811 extends in the vertical direction. The rib 811 has a hollow prism shape (frame shape). In the first embodiment, another rib 811a is provided at an edge of an opposed face 8a opposed to the first surface 2a, and part of the rib 811a configures part of the rib 811. The bottom portion 812 is part of the main body portion 80, and has a flat plate shape. The bottom portion 812 is fixed to the upper end portion of the rib 811 so as to close the opening of the rib 811 (the opening of the land 31 or 32).

The recess 81 forms a clearance C1 or C2 between the electronic component A or B and the first lid element 8 (main body portion 80) such that the first lid element 8 is not in contact with the electronic component A or B. In the first embodiment, height of the electronic component A is lower than height of the electronic component B, and the depth of the land 31 or 32 is equal to the depth of the recess 81; hence, the clearance C1 is larger than the clearance C2 (C1>C2). The recess 81 forms the clearance C1 or C2 while at least the first lid element 8 is disposed over the resin element 2 (at least before overmolding). The recess 81 and the land 31 or 32 thus form a closed space in which the electronic component A or B is disposed.

Furthermore, the clearances C1 and C2 of the first embodiment are set based on the deformation amount (estimated deformation amount) of the first lid element 8 estimated by calculating or simulating a pressure during the overmolding (secondary molding) to be performed later. In other words, the recess 81 is formed based on the estimated deformation amount of the first lid element 8 estimated through advance calculation of influence during the overmolding. The recess 81 of the first embodiment forms the clearance C1 or C2 larger than the estimated deformation amount such that the electronic component A or B does not come into contact with the first lid element 8 even after the overmolding. The clearances C1 and 02 are each set to be equal to or larger than the minimum clearance that can prevent the electronic component A or B from coming into contact with the first lid element 8. That is, the recess 81 of the first embodiment forms the clearance even after the overmolding (after deformation).

The first lid element 8 has an undepicted fixing means for fixation (temporarily fixation) to the resin element 2. The fixing means is configured to form an engagement relation with the resin element 2, and includes, for example, a groove into which a pin formed in the resin element 2 is press-fitted, or a pin to be press-fitted into a groove formed in the resin element 2. Furthermore, as described above, the sidewall is formed on the entire periphery of the lower surface (opposed surface 8 a) of the main body portion 80 by the rib 811a (and/or the rib 811) to prevent the first surface 2a of the resin element 2 from being exposed.

In the first embodiment, the resin of the resin element 2 is different from the resin of the first lid element 8. The resin of the resin element 2 withstands jointing operation such as soldering. The resin of the first lid element 8 has a thermal resistance lower than the resin element 2. However, the resins may be the same.

According to the electronic circuit component of the first embodiment, since the first lid element 8 has the recess 81 corresponding to the land 31 or 32, even if the first lid element 8 is deformed by the later overmolding, the deformation is absorbed by the clearance C1 or C2, and stress applied to the electronic component is suppressed. Furthermore, according to the first embodiment, since the clearance C1 or C2 is set based on the estimated deformation amount, a clearance can also be formed between the electronic component A or B and the first lid element 8 even after the overmolding. This suppresses contact between the first lid element 8 and the electronic component A or B due to deformation of the first lid element 8 during the overmolding, and thus stress applied to the electronic component A or B is more reliably suppressed. Furthermore, formation of the recess 81 based on the estimated deformation amount suppresses formation of an excessive clearance, and suppresses an increase in size of the electronic circuit component.

Furthermore, in the first embodiment, one electronic component A or B is disposed for one land 31 or 32, and the recess 81 is provided for each of the lands 31 and 32. Consequently, a firm closed space is formed by one land 31 or 32 and one recess 81 for each of the electronic components A and B, which further suppresses application of stress to the electronic component A or B.

According to the first embodiment, even if the bottom portion 812 is pushed into the opening of the recess 81 by the overmolding, the electronic component A or B does not project from the first surface 2a while being accommodated in the land 31 or 32. Hence, the sidewall of the land 31 or 32 suppresses the application of stress to the electronic component A or B.

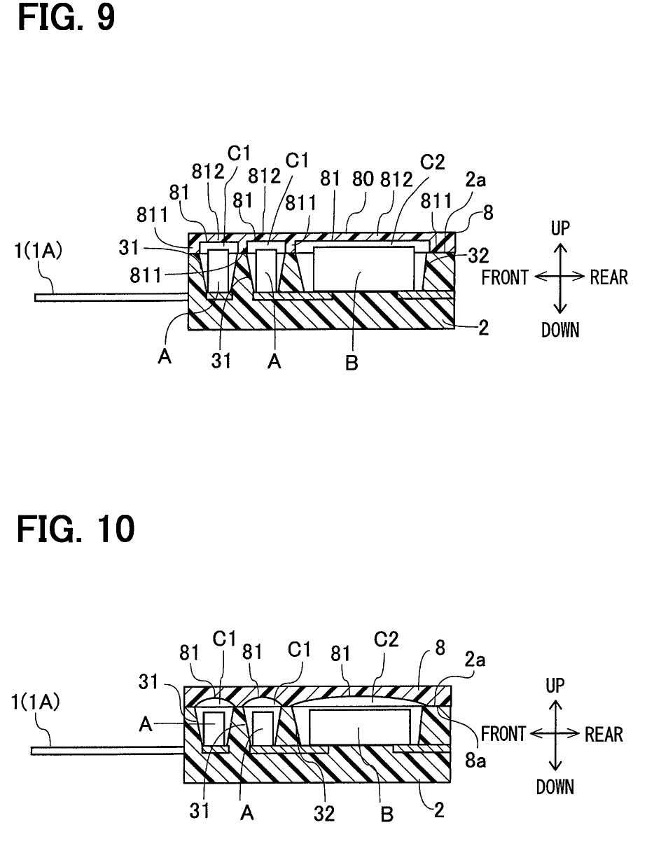

As shown in FIG. 9, the upper end portion of the electronic component A or B may project from the first surface 2a. That is, the height (vertical length) of the electronic component A or B may be larger than the depth (vertical length) of the land 31 or 32. In such a case, the recess 81 may be formed so as to form a clearance equal to or larger than the clearance C2 between the electronic component A or B and the first lid element 8. This configuration further facilitates disposition operation and soldering operation of the electronic component A or B.

### Second Embodiment

An electronic circuit component of a second embodiment is different from the first embodiment mainly in that the recess 81 is not formed with the rib 811. Hence, different portions are merely described. The same reference numerals as those in the first embodiment each indicate the same configuration as in the first embodiment while referring to the preceding description.

As shown in FIG. 10, the recess 81 of the second embodiment is formed by recessing the opposed face 8a of the first lid element 8 opposed to the first surface 2a in a concave arc shape. As with the first embodiment, the recess 81 is formed so as to be opposed to the land 31 or 32. The recess 81 forms a clearance C1 or C2 between the electronic component A or B and the first lid element 8. This configuration exhibits the same effect as in the first embodiment.

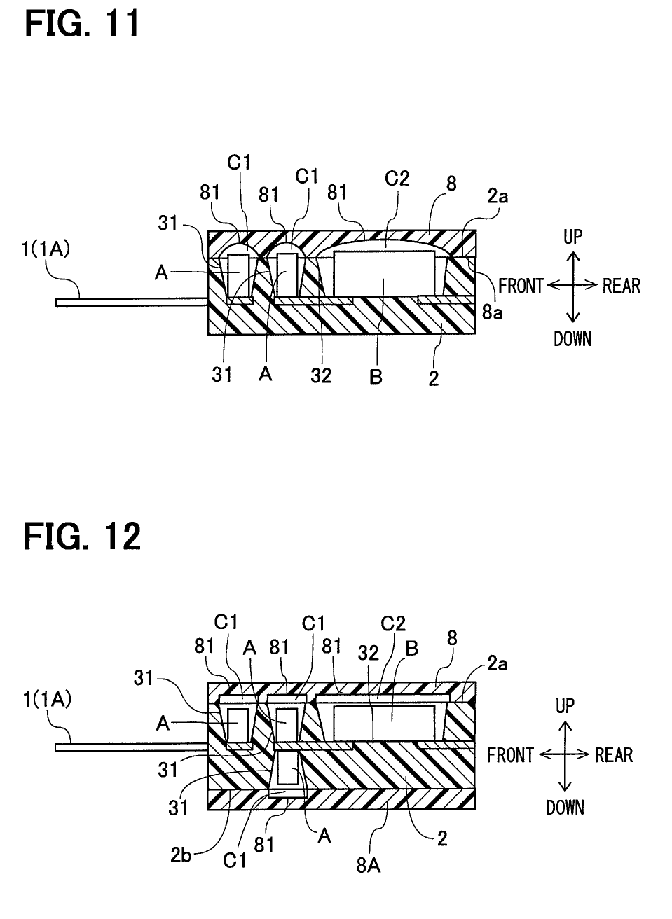

As shown in FIG. 11, as with the first embodiment, the upper end portion of the electronic component A or B may also project from the first surface 2a in the second embodiment. In the first or second embodiment, part of the upper end portion of the electronic component A or B may project from the first surface 2a. In such a case, the recess 81 may be formed to have a depth so as to provide the clearance equal to or larger than the clearance C2. For the first embodiment, the rib 811 may be formed in accordance with the most projecting one between the electronic components A and B. For the second embodiment, each recess 81 may have a depth in accordance with the projection amount of each of the electronic components A and B.

### Third Embodiment

An electronic circuit component of a third embodiment is different from the first embodiment mainly in that the electronic component A or B is also disposed on a second surface 2b (lower surface) side of the resin element 2. Hence, different portions are merely described. The same reference numerals as those in the first embodiment each indicate the same configuration as in the first embodiment while referring to the preceding description.

As shown in FIG. 12, in the third embodiment, the land 31 corresponding to the electronic component A is also provided in the second surface 2b of the resin element 2. The second surface 2b is a surface of the resin element 2 opposite to the first surface 2a. That is, the electronic component A is disposed on either side of the leadframe 1. The land 31 has a configuration similar to a configuration of the land 31 on the first surface 2a, and an undepicted terminal portion connectable to the electronic component is exposed on the bottom Z.

The electronic circuit component of the third embodiment further includes a second lid element 8A disposed on the second surface 2b. The second lid element 8A has the same configuration as that of the first lid element 8. That is, a recess (corresponding to “second recess”) 81 is provided in a portion, which is opposed to the land 31 of the second surface 2b, of the second lid element 8A. As with the first embodiment, the recess 81 of the second lid element 8A forms a clearance C1 between the electronic component A and the second lid element 8A. The second surface 2b of the resin element 2 is covered with the second lid element 8A. A land 32 on which the electronic component B is disposed may also be provided on the second surface 2b. In such a case, the recess 81 corresponding to the land 32 is provided in the second cover lid element 8A as with the first embodiment.

According to such a configuration, the same effect as in the first embodiment is exhibited, and the mounting amount of the electronic components A and B can be increased. In the third embodiment, the recesses 81 of the first lid element 8 and/or the second lid element 8A may each be a recess 81 without the rib 811 as with the second embodiment.

### Fourth Embodiment

An electronic circuit component of a fourth embodiment is different from the first embodiment in that the component is overmolded. Hence, different portions are merely described. The same reference numerals as those in the first embodiment each indicate the same configuration as in the first embodiment while referring to the preceding description.

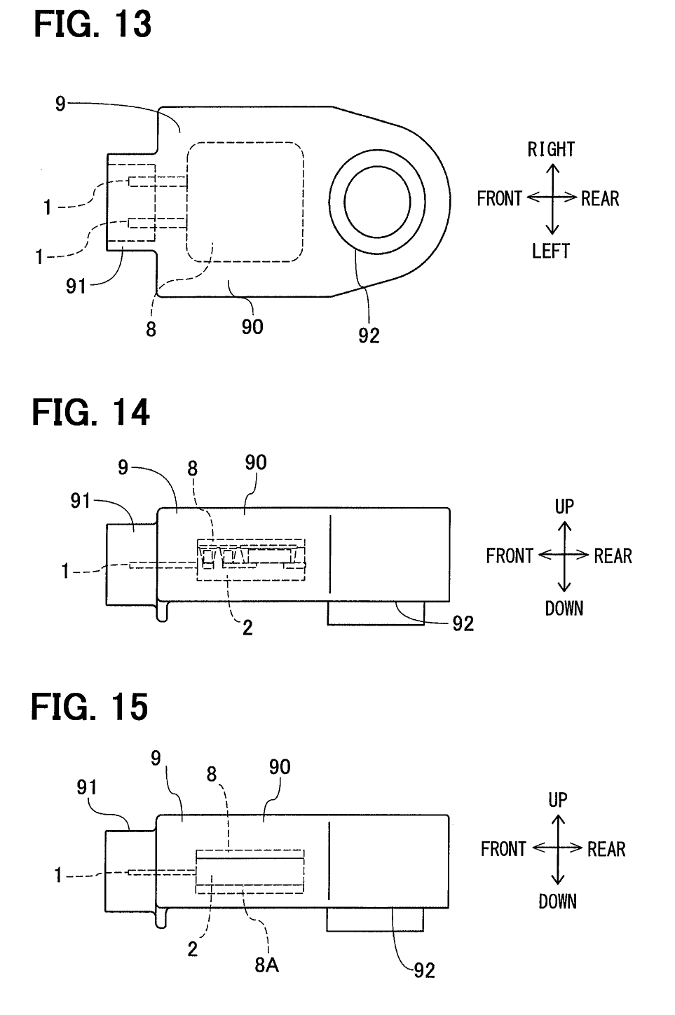

As shown in FIGS. 13 and 14, the electronic circuit component of the fourth embodiment further includes an overmold element 9. The overmold element 9 is a resin element covering part of the leadframe 1, the resin element 2, and the first lid element 8. The overmold element 9 is formed by overmolding (secondary-molding) the entire electronic circuit component of the first embodiment with a resin (for example, PBT).

The overmold element 9 includes a main body part 90 covering the electronic circuit component of the first embodiment, a connector case part 91 projecting from one end portion of the main body part 90, and a fixing part 92 formed on an end portion (here, the other end portion) of the main body part 90. The connector case part 91 has a cylindrical shape, within which a connector terminal part 1A as part of the leadframe 1 is exposed. A fixing metal element for fixing the vehicle is inserted in the fixing part 92.

The recess 81 of the fourth embodiment forms a clearance between the electronic component A or B and the first lid element 8. That is, even if the first lid element 8 is deformed by the secondary molding for forming the overmold element 9, a certain clearance is provided and thus the electronic component A or B is not in contact with the first lid element 8. This configuration suppresses application of stress to the electronic component A or B during the overmolding. The overmold element 9 of the fourth embodiment is not limitedly provided in the electronic circuit component of the first embodiment, but may be provided in the electronic circuit component of the second or third embodiment. For example, as shown in FIG. 15, the fourth embodiment may be designed such that the electronic circuit component of the third embodiment is disposed in the overmold element 9.

The present disclosure is not limited to the above embodiments. Modifications of the above embodiments are now described. For example, the side face Y of the land 31 or 32 may not be inclined. However, the side face Y is inclined such that opening area increases as going to the upside (opening side) as in that embodiment, which facilitates disposition operation of the electronic component A or B. Furthermore, a planar shape (a shape as viewed from the upside) of the land 31 or 32 is not limited to a rectangular shape, and may be a circular shape or another polygonal shape depending on electronic components. In such a case, the shape of the recess 81 may also be a shape corresponding to the land 31 or 32.

Furthermore, depths of the recesses 81 may be different from one another. For example, each recess 81 may have a depth according to the electronic component A or B. In addition, the sectional shape of the recess 81 of the second embodiment is not limited to an arc shape like a dome, but may be a horn shape or a combination of a horn shape and an arc shape. Furthermore, the recess 81 may not form a clearance based on the estimated deformation amount. Formation of only a slight clearance by the recess 81 leads to absorption of deformation of the lid element 8 or 8A, and thus leads to suppression of stress application during the overmolding.

The type and the mode of the electronic component A or B are not limited to those in the above embodiments. The size and the number of the terminal portions (40 to 57) in the land 31 or 32 may be set so as to correspond to the size and the number of terminals of an electronic component to be mounted. That is, the terminal portions (40 to 57) can be disposed in the land 31 or 32 depending on the type and the mode of the electronic component. The anchor parts 6 and 7 may not be provided. Furthermore, the anchor part 6 or 7 may be provided in one or more terminal portions 40 to 57. The surfaces (2a, 2b, 8a) such as the first surface 2a are each a planar portion in the above embodiments, but conceptually include a surface having irregularities (one-side portion).

The leadframe 1 may be formed of a copper material, an alloy material, or a Kovar material used for IC components. The leadframe 1 may be subjected to surface treatment (for example, tinning) to improve solderability. The electronic circuit component of each of the above-described embodiments can be used in, for example, an acceleration sensor or an electronic control unit (ECU).

While the present disclosure has been described with reference to embodiments thereof, it is to be understood that the disclosure is not limited to the embodiments and constructions. The present disclosure is intended to cover various modification and equivalent arrangements. In addition, the various combinations and configurations, other combinations and configurations, including more, less or only a single element, are also within the spirit and scope of the present disclosure.

1-10. (canceled)

11. An electronic circuit component comprising:
an electronic component;
a leadframe that forms a circuit pattern corresponding to an arrangement of the electronic component;
a resin element in which a part of the leadframe is disposed by insert molding;
a first lid element that covers a first surface of the resin element on which the electronic component is arranged, wherein the first surface of the resin element includes a concave land in which the electronic component is arranged; and
a plurality of terminal portions that is arranged on a bottom surface of the land, wherein:
the plurality of terminal portions is a part of the leadframe and is electrically connected to the electronic component;
a part of the first lid element that is opposed to the land includes a recess that defines a clearance between the electronic component and the first lid element; and
the recess is formed based on an estimated deformation amount of the first lid element, which is estimated through advance calculation of influence of overmolding of the electronic circuit component.

12. The electronic circuit component according to claim 11, further comprising:
a second lid element that is disposed on a second surface of the resin element on an opposite side of the resin element from the first surface, wherein the second surface of the resin element includes the concave land in which the electronic component is arranged; and
a plurality of terminal portions that is arranged on the bottom surface of the land of the second surface, wherein:
the plurality of terminal portions for the second surface is a part of the leadframe and is electrically connected to the electronic component; and
a part of the second lid element that is opposed to the land of the second surface includes a second recess that defines a clearance between the electronic component and the second lid element.

13. The electronic circuit component according to claim 11, wherein:
the land is one of a plurality of lands;
the electronic component is one of a plurality of electronic components; and
each one of the plurality of electronic components is arranged in a corresponding one of the plurality of lands.

14. The electronic circuit component according to claim 11, wherein a sidewall of the land is formed to have such a height that the electronic component does not project from the first surface.

15. The electronic circuit component according to claim 11, wherein the recess includes:
a rib that is arranged along an entire periphery of an edge portion of the land; and
a bottom portion that serves as a bottom surface of the recess with the rib as its sidewall.

16. The electronic circuit component according to claim 11, wherein:
the recess is formed by recessing an opposed surface of the first lid element; and
the opposed surface is opposed to the first surface.

17. An electronic circuit component comprising:
an electronic component;
a leadframe that forms a circuit pattern corresponding to an arrangement of the electronic component;
a resin element in which a part of the leadframe is disposed by insert molding;
a first lid element that covers a first surface of the resin element on which the electronic component is arranged, wherein the first surface of the resin element includes a concave land in which the electronic component is arranged; and
a plurality of terminal portions that is arranged on a bottom surface of the land, wherein:
the plurality of terminal portions is a part of the leadframe and is electrically connected to the electronic component; and
a part of the first lid element that is opposed to the land includes a recess that defines a clearance between the electronic component and the first lid element, the electronic circuit component further comprising an overmold element that covers the resin element and the first lid element, wherein the recess defines the clearance between the electronic component and the first lid element with the overmold element arranged.

18. The electronic circuit component according to claim 17, wherein the recess is formed based on an estimated deformation amount of the first lid element, which is estimated through advance calculation of influence of overmolding of the electronic circuit component.

19. The electronic circuit component according to claim 17, wherein:
the land is one of a plurality of lands;
the electronic component is one of a plurality of electronic components; and
each one of the plurality of electronic components is arranged in a corresponding one of the plurality of lands.

20. The electronic circuit component according to claim 17, wherein a sidewall of the land is formed to have such a height that the electronic component does not project from the first surface.

21. The electronic circuit component according to claim 17, wherein the recess includes:
a rib that is arranged along an entire periphery of an edge portion of the land; and
a bottom portion that serves as a bottom surface of the recess with the rib as its sidewall.

22. The electronic circuit component according to claim 17, wherein:
the recess is formed by recessing an opposed surface of the first lid element; and
the opposed surface is opposed to the first surface.

23. An electronic circuit component comprising:
an electronic component;
a leadframe that forms a circuit pattern corresponding to an arrangement of the electronic component;
a resin element in which a part of the leadframe is disposed by insert molding;
a first lid element that covers a first surface of the resin element on which the electronic component is arranged, wherein the first surface of the resin element includes a concave land in which the electronic component is arranged; and
a plurality of terminal portions that is arranged on a bottom surface of the land, wherein:
the plurality of terminal portions is a part of the leadframe and is electrically connected to the electronic component; and
a part of the first lid element that is opposed to the land includes a recess that defines a clearance between the electronic component and the first lid element, the electronic circuit component further comprising:
a second lid element that is disposed on a second surface of the resin element on an opposite side of the resin element from the first surface, wherein the second surface of the resin element includes the concave land in which the electronic component is arranged; and
a plurality of terminal portions that is arranged on the bottom surface of the land of the second surface, wherein:
the plurality of terminal portions for the second surface is a part of the leadframe and is electrically connected to the electronic component;
a part of the second lid element that is opposed to the land of the second surface includes a second recess that defines a clearance between the electronic component and the second lid element; and
the second recess is formed based on an estimated deformation amount of the second lid element, which is estimated through advance calculation of influence of overmolding of the electronic circuit component.

24. The electronic circuit component according to claim 23, wherein the recess is formed based on an estimated deformation amount of the first lid element, which is estimated through advance calculation of influence of overmolding of the electronic circuit component.

25. The electronic circuit component according to claim 23, wherein:
the land is one of a plurality of lands;
the electronic component is one of a plurality of electronic components; and
each one of the plurality of electronic components is arranged in a corresponding one of the plurality of lands.

26. The electronic circuit component according to claim 23, wherein a sidewall of the land is formed to have such a height that the electronic component does not project from the first surface.

27. The electronic circuit component according to claim 23, wherein the recess includes:
a rib that is arranged along an entire periphery of an edge portion of the land; and
a bottom portion that serves as a bottom surface of the recess with the rib as its sidewall.

28. The electronic circuit component according to claim 23, wherein:
the recess is formed by recessing an opposed surface of the first lid element; and
the opposed surface is opposed to the first surface.

29. An electronic circuit component comprising:
an electronic component;
a leadframe that forms a circuit pattern corresponding to an arrangement of the electronic component;
a resin element in which a part of the leadframe is disposed by insert molding;
a first lid element that covers a first surface of the resin element on which the electronic component is arranged, wherein the first surface of the resin element includes a concave land in which the electronic component is arranged; and
a plurality of terminal portions that is arranged on a bottom surface of the land, wherein:
the plurality of terminal portions is a part of the leadframe and is electrically connected to the electronic component; and
a part of the first lid element that is opposed to the land includes a recess that defines a clearance between the electronic component and the first lid element, the electronic circuit component further comprising:
a second lid element that is disposed on a second surface of the resin element on an opposite side of the resin element from the first surface, wherein the second surface of the resin element includes the concave land in which the electronic component is arranged; and
a plurality of terminal portions that is arranged on the bottom surface of the land of the second surface, wherein:
the plurality of terminal portions for the second surface is a part of the leadframe and is electrically connected to the electronic component; and
a part of the second lid element that is opposed to the land of the second surface includes a second recess that defines a clearance between the electronic component and the second lid element, the electronic circuit component further comprising an overmold element that covers the resin element, the first lid element, and the second lid element, wherein the recess and the second recess define clearances between the electronic component and the first lid element and between the electronic component and the second lid element in a state where the overmold element covering the resin element, the first lid element, and the second lid element is arranged.

30. The electronic circuit component according to claim 29, wherein the second recess is formed based on an estimated deformation amount of the second lid element, which is estimated through advance calculation of influence of overmolding of the electronic circuit component.

31. The electronic circuit component according to claim 29, wherein the recess is formed based on an estimated deformation amount of the first lid element, which is estimated through advance calculation of influence of overmolding of the electronic circuit component.

32. The electronic circuit component according to claim 29, wherein:
the land is one of a plurality of lands;
the electronic component is one of a plurality of electronic components; and
each one of the plurality of electronic components is arranged in a corresponding one of the plurality of lands.

33. The electronic circuit component according to claim 29, wherein a sidewall of the land is formed to have such a height that the electronic component does not project from the first surface.

34. The electronic circuit component according to claim 29, wherein the recess includes:
a rib that is arranged along an entire periphery of an edge portion of the land; and
a bottom portion that serves as a bottom surface of the recess with the rib as its sidewall.

35. The electronic circuit component according to claim 29, wherein:
the recess is formed by recessing an opposed surface of the first lid element; and
the opposed surface is opposed to the first surface.
